(19) United States
(12) Patent Application Publication
(10) Pub. No.: US 2024/0337682 A1
(43) Pub. Date: Oct. 10, 2024

(54) SOURCE MEASUREMENT UNIT WITH RESISTOR-CAPACITOR CHARGING CIRCUIT

(71) Applicant: Texas Instruments Incorporated, Dallas, TX (US)

(72) Inventor: Rajavelu Thinakaran, Bangalore (IN)

(21) Appl. No.: 18/478,850

(22) Filed: Sep. 29, 2023

(30) Foreign Application Priority Data
Apr. 4, 2023 (IN) 202341025460

(51) Int. Cl. G01R 31/28; H03K 17/687

(52) U.S. Cl. CPC G01R 31/2834; H03K 17/6871

(57) ABSTRACT

In described examples, a system includes a resistor, a capacitor coupled to the resistor to form an RC circuit, and a charging circuit. The charging circuit is coupled to the resistor and to the capacitor. The charging circuit is configured to determine a voltage across the resistor, and to provide a current to the capacitor to increase a rate of charging or discharging of the capacitor. A magnitude and a polarity of the current are responsive to the voltage across the resistor. In some examples, the RC circuit is configured to compensate for a load capacitance of a parametric measurement unit, a source measurement unit, or a device power supply that is part of an automatic test equipment.

### CROSS-REFERENCE TO RELATED APPLICATION

This application claims the benefit of, and priority to, India Provisional Application No. 202341025460, filed Apr. 4, 2023, which is incorporated herein by reference.

### TECHNICAL FIELD

This application relates generally to automatic test equipment (ATE), and more particularly to improving settling time of a force voltage mode of a source measurement unit (SMU).

### BACKGROUND

An ATE is used to perform automatically sequenced tests on one or more devices under test (DUTs), such as integrated circuits (ICs) or system-on-chips (SoCs). In some examples, an ATE is used to perform wafer testing, or to test packaged parts. In some examples, an ATE is used to test avionics, or to test electronic modules for automobiles or industrial systems. Safety or other criteria may require ATE testing prior to part deployment. Accordingly, where an ATE testing is desired or required prior to part installation, a rate at which the ATE testing can be completed for a part limits a manufacturing throughput for the part. In some examples, sequences of test signals to be applied, and corresponding DUT internal and output signals to be measured, are programmed into an ATE in response to DUT design.

### SUMMARY

In described examples, a system includes a resistor, a capacitor coupled to the resistor to form an RC circuit, and a charging circuit. The charging circuit is coupled to the resistor and to the capacitor. The charging circuit is configured to determine a voltage across the resistor, and to provide a current to the capacitor to increase a rate of charging or discharging of the capacitor. A magnitude and a polarity of the current are responsive to the voltage across the resistor. In some examples, the RC circuit is configured to compensate for a load capacitance of a parametric measurement unit, a source measurement unit, or a device power supply that is part of an ATE.

### BRIEF DESCRIPTION OF THE DRAWINGS

FIG. 1 is a functional block diagram of an example ATE system.

FIG. 2A is a functional block diagram of another example ATE system.

FIG. 2B is a functional block diagram of a third example ATE system.

FIG. 3 is a functional block and circuit diagram of the force voltage feedback loop including the force amp and voltage sense circuit of FIG. 2.

FIG. 4A is a circuit diagram of a first example of the charging circuit of FIG. 3.

FIG. 4B is a circuit diagram of an alternative example of the charging circuit of FIG. 3.

FIG. 4C is a circuit diagram of another alternative example of the charging circuit of FIG. 3.

FIG. 5 is an example process for charging and discharging of an RC circuit.

FIG. 6 is an example graph of force voltage settling time against load capacitance for the force voltage feedback loop of FIG. 3, with and without the charging circuit of FIG. 3.

### DETAILED DESCRIPTION

In some examples, an ATE uses parametric measurement units (PMUs), source measurement units (SMUs), or device power supplies (DPSs) to provide test signals for, and measure internal or output signal levels of, respective DUTs. An example operational mode for an SMU is a force voltage mode in which the SMU forces a specified supply voltage level at a supply voltage pin of a DUT and measures resulting DUT current into or out of the pin, or voltage at the pin.

In some examples, an operational amplifier (op amp) is used to determine a voltage of a test signal applied by an SMU to a DUT. The op amp includes a resistor/capacitor (RC) circuit used to compensate for a widely variable load capacitance of the DUT. Examples are described with a charging circuit to improve a speed with which the op amp provides a test signal voltage at its output in response to a step change in input voltage, where limitations otherwise could be caused by a settling time constant of the RC circuit. Particularly, a charging circuit is used to accelerate charging and discharging of the capacitor of the RC circuit.

The charging circuit can accomplish its acceleration in response to voltage polarity in the RC circuit. Particularly, the RC circuit resistor has a current—and, accordingly, a voltage—with a first polarity if the RC circuit capacitor is charging. The RC circuit resistor has a current with a second polarity if the RC circuit capacitor is discharging. The charging circuit compares the voltage across the resistor of the RC circuit to a threshold voltage. If the voltage across the resistor of the RC circuit is greater (more positive) than the threshold voltage, then the charging circuit provides a current with the first polarity to accelerate charging of the capacitor of the RC circuit. If the voltage across the resistor of the RC circuit is less (more negative) than a negative threshold voltage (the threshold voltage with the same magnitude and opposite sign), then the charging circuit provides a current with the second polarity to accelerate discharging of the capacitor of the RC circuit.

In some examples, an RC circuit used to compensate for load capacitance of a DUT uses an on-chip resistor and an on-board (but not necessarily on-chip) capacitor, where the capacitor is relatively large. In some examples, a DUT has a wide range of possible load capacitance. In some examples, use of a charging circuit as described above enables accelerated settling time of the RC compensation circuit without using multiple different RC circuit capacitors to address different portions of the DUT load capacitance range.

Herein, some structures or signals that are distinct but closely related have reference numbers that use a [number][letter] format, such as charging circuits 318a, 318b, and 318c. In some examples, these structures or signals are referred to generally, in the singular or as a group, using the [number] and without the [letter], such as the charging circuits 318. Also, the same reference numbers or other reference designators are used in the drawings to designate features that are closely related structurally and/or functionally.

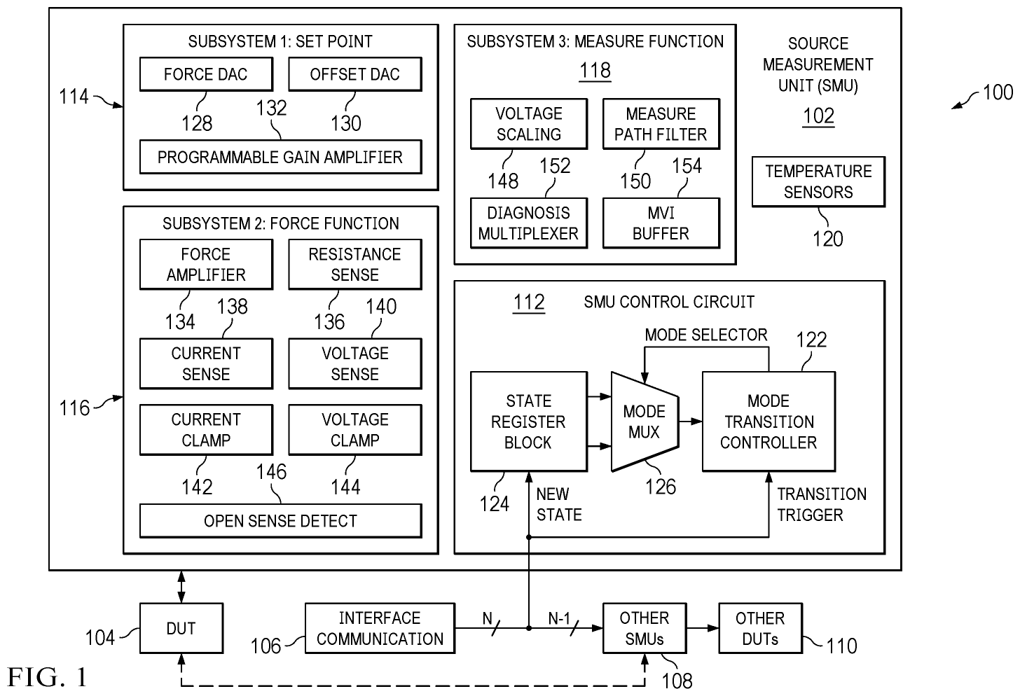

FIG. 1 is a functional block diagram of an example ATE system 100. The ATE system includes an SMU 102, a DUT 104 controlled by the SMU 102, an interface communication circuit 106, other SMUs 108, and other DUTs 110. DUTs (such as the DUT 104 or other DUTs 110) each have a (variable) first number of inputs (such as pins) that can receive test signals. Also, SMUs (such as the SMU 102 or other SMUs 108) each have a (variable) second number of outputs that can provide test signals. The first number of inputs and the second number of outputs may be different. Accordingly, the DUT 104 may be controlled by one or more of the other SMUs 108 in addition to the SMU 102 (indicated by a dotted line). Similarly, the other DUTs 110 are respectively controlled by one or more of the other SMUs 108. Here, a SMU controlling a DUT refers to the SMU providing test signals to, and receiving response signals from, the DUT. The interface communication circuit 106 distributes sequenced operational state setting information to the SMU 102 and the other SMUs 108 to cause the various SMUs 102 and 108 to apply selected test signals to, and receive response signals from, respective ones of the various DUTs 104 and 110.

The SMU 102 includes a SMU control circuit 112, a set point subsystem (subsystem 1) 114, a force function subsystem (subsystem 2) 116, a measure function subsystem (subsystem 3) 118, and temperature sensors 120. The SMU control circuit 112 includes a mode transition controller 122, a state register block 124, and a mode multiplexer (MUX) 126.

The set point subsystem 114 includes a force digital to analog controller (DAC) 128, an offset DAC 130, and a programmable gain amplifier 132. The force function subsystem 116 includes a force amplifier 134, a resistance sense circuit 136, a current sense circuit 138, a voltage sense circuit 140, a current clamp 142, a voltage clamp 144, and an open sense detect (OSD) circuit 146. The measure function subsystem 118 includes a voltage scaling circuit 148, a measure path filter 150, a diagnosis MUX 152, and a measure voltage/current (MVI) buffer 154.

In some examples, the SMU 102 includes additional, fewer, and/or different subsystems. In some examples, the set point, force function, and measure function subsystems 114, 116, and 118 respectively include additional, fewer, and/or different functional blocks.

The interface communication circuit 106 provides new SMU 102 operating state information to the state register block 124 and a Transition Trigger to the respective mode transition controllers 122 of a number N different SMUs. The N different SMUs include the SMU 102 and N minus one other SMUs 108. An ENABLE value of the Transition Trigger signals the SMU control circuit 112 to transition the SMU 102 (or other SMU 108) to a new operating state stored by the state register block 124.

In some examples, the interface communication circuit 106 controls the N SMUs (that is, the SMU 102 and other SMUs 108) using N communication buses, such as serial buses. Each communication bus may be multiple lines wide. In some examples, N equals 64. In some examples, the interface communication circuit 106 serially provides the new state and the transition trigger to respective ones of the SMU 102 and other SMUs 108 via a corresponding bus. In some examples, a communication bus may include a separate connection from the interface communication circuit 106 to a dedicated input (such as a pin) of the SMU 102 (or other SMU 108) to provide a transition trigger signal.

The SMU 102 and other SMUs 108 provide test signals to the DUT 104 or other DUTs 110, and receive and sense signals of the DUT 104 or other DUTs 110 (respectively), according to operating state information stored by the respective state register blocks 124 of the SMU 102 or other SMUs 108. In some examples, connections of the SMU 102 to and from the DUT 104, and of the other SMUs 108 to and from the DUT 104 and/or other DUTs 110, are multiple lines corresponding to various different test signals and response signals.

The state register block 124 provides state information (mode and configuration information) from each of two different sets of registers to the mode MUX 126. The mode MUX 126 also receives a Mode Selector signal from the mode transition controller 122. The mode MUX 126 provides state information from one of the two different sets of registers of the state register block 124 to the mode transition controller 122. The mode MUX 126 selects between the two different sets of state information in response to a value of the Mode Selector signal. The mode transition controller 122 changes the value of the Mode Selector signal in response to the Transition Trigger. Accordingly, after the Transition Trigger enters the ENABLE state, the value of the Mode Selector signal is changed, the mode MUX 126 provides a new, different set of state information to the mode transition controller 122, and the mode transition controller 122 loads the new set of state information. Once signal values corresponding to the new set of state information settle, the SMU 102 operates (providing test signals to, and sensing resulting response signals of, the DUT 104) using the new set of state information.

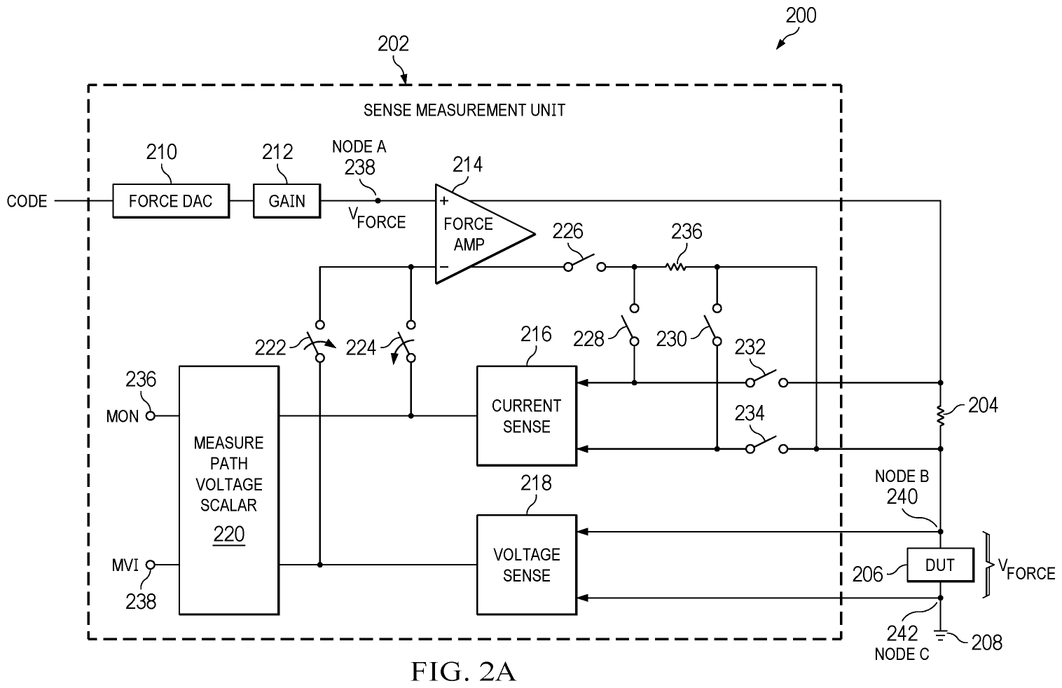

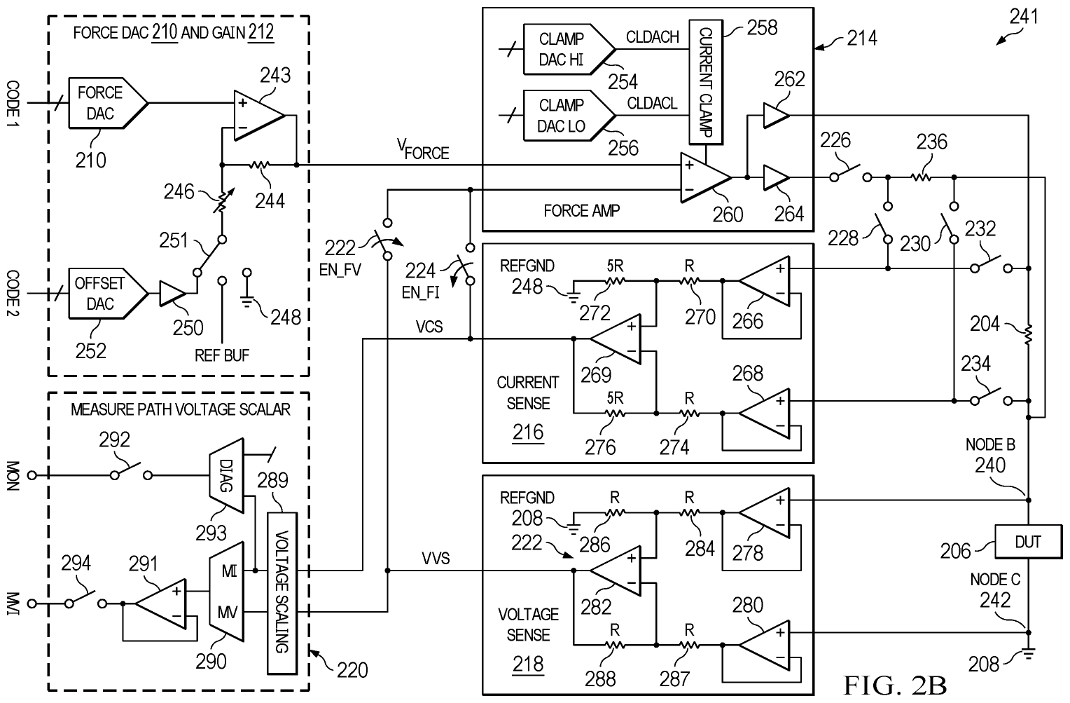

FIG. 2A is a functional block diagram of another example ATE system 200. The ATE system 200 may also be considered to be an alternative representation of the ATE system 100 of FIG. 1. The ATE system 200 includes an SMU 202, an external resistor 204, a DUT 206, and a ground 208. The SMU 202 includes a force DAC 210, a gain circuit 212, a force amplifier (force amp) 214, a current sense circuit 216, a voltage sense circuit 218, and a measure path voltage scalar (MPVS) circuit 220. In examples described herein, the force amp 214 is the op amp referred to above. The SMU 202 also includes a first switch 222, a second switch 224, a third switch 226, a fourth switch 228, a fifth switch 230, a sixth switch 232, a seventh switch 234, and a sense resistor 236. In some examples, the SMU 202 is fabricated on an IC. In some examples, different portions of the SMU 202 are fabricated on different ICs. In some examples, the force amp 214 is fabricated on an IC.

In some examples, the force DAC 210 and gain circuit 212 are part of or correspond to the set point subsystem 114. The force amp 214, current sense circuit 216, and voltage sense circuit 218 are part of or correspond to the force function subsystem 116. The MPVS circuit 220 is part of or corresponds to the measure function subsystem 118.

An input of the force DAC 210 receives a code to control a voltage provided by the force DAC 210. An output of the force DAC 210 is connected to an input of the gain circuit 212. An output of the gain circuit 212 is connected to a non-inverting input of the force amp 214. A first node (node A) 238 is located at the non-inverting input of the force amp 214. A first output of the force amp 214 is connected to a first terminal of the third switch 226. A second output of the force amp 214 is connected to a second terminal of the sixth switch 232 and a first terminal of the external resistor 204.

A second terminal of the third switch 226 is connected to a first terminal of the fourth switch 228 and a first terminal of the sense resistor 236. A second terminal of the fourth switch 228 is connected to a first input of the current sense circuit 216 and a first terminal of the sixth switch 232. A second terminal of the fifth switch 230 is connected to a second input of the current sense circuit 216 and a first terminal of the seventh switch 234.

A second terminal of the sense resistor 236 is connected to a first terminal of the fifth switch 230, a second terminal of the seventh switch 234, a second terminal of the external resistor 204, a first input of the voltage sense circuit 218, and a second node (node B) 240, which is located at the input of the DUT 206. An output of the DUT 206 is connected to a third node (node C) 242, which is connected to a second input of the voltage sense circuit 218 and the ground 208.

An output of the current sense circuit 216 is connected to a first input of the MPVS circuit 220 and a first terminal of the second switch 224. An output of the voltage sense circuit 218 is connected to a second input of the MPVS circuit 220 and a first terminal of the first switch 222. An inverting input of the force amp 214 is connected to a second terminal of the first switch 222 and a second terminal of the second switch 224.

As illustrated in FIG. 2A, responsive to the SMU 202 being in force voltage mode, the first switch 222 is closed (turned on and conducting) and the second switch 224 is open (turned off and not conducting). As a result, the force amp 214 receives feedback from the voltage sense circuit 218, which senses the voltage differential across the DUT 206. In some examples, the force DAC 210 outputs a voltage in response to a code, and the gain circuit 212 applies a gain to the voltage output by the force DAC 210, so that a voltage at node A 238 equals V_{FORCE}. V_{FORCE} is a voltage intended to be applied across the DUT 206 as a test signal while the SMU 202 is in force voltage mode. Accordingly, the voltage from node B 240 to node C 242 is intended to equal V_{FORCE}. Thus, the first or second output of the force amp 214 to equal V_{FORCE} responsive to the feedback loop in the force voltage mode.

In some examples, in an internal resistor mode, the third, fourth, and fifth switches 226, 228 and 230 are closed, the sixth and seventh switches 232 and 234 are open, and the first output of the force amplifier 214 is controlled to equal V_{FORCE}. In an external resistor mode, the third, fourth, and fifth switches 226, 228 and 230 are open, the sixth and seventh switches 232 and 234 are closed, and the second output of the force amplifier 214 is controlled to equal V_{FORCE}.

As described above, while the SMU 202 is in force voltage mode, it forces (supplies) a voltage at a pin of the DUT 206 and measures resulting current through or voltage at the pin. In some examples, a DUT 206 pin is a supply voltage pin at which the SMU 202, in force voltage mode, forces a specified DUT supply voltage and measures resulting supply current. In some examples, an internal resistor of the DUT 206 is connected to the DUT 206 pin. An SMU 202 in force voltage mode can be used to force a specific voltage at the DUT 206 pin and measure current through the DUT 206 pin. Measuring current enables determination of the resistance of the resistor (R=V/I).

As described, the voltage sense circuit 218 provides feedback to the force amp 214 by the first switch 222. Accordingly, the voltage sense circuit 218 enables a negative feedback loop so that the force amp 214 controls the voltage across the DUT 206 responsive to V_{FORCE}. In some examples, the voltage sense circuit 218 has unity gain, and the voltage across the DUT 206 is controlled to equal V_{FORCE}. In some examples, the voltage sense circuit 218 has a different gain, so that the voltage across the DUT 206 equals V_{FORCE} times a multiplier responsive to the gain of the voltage sense circuit 218.

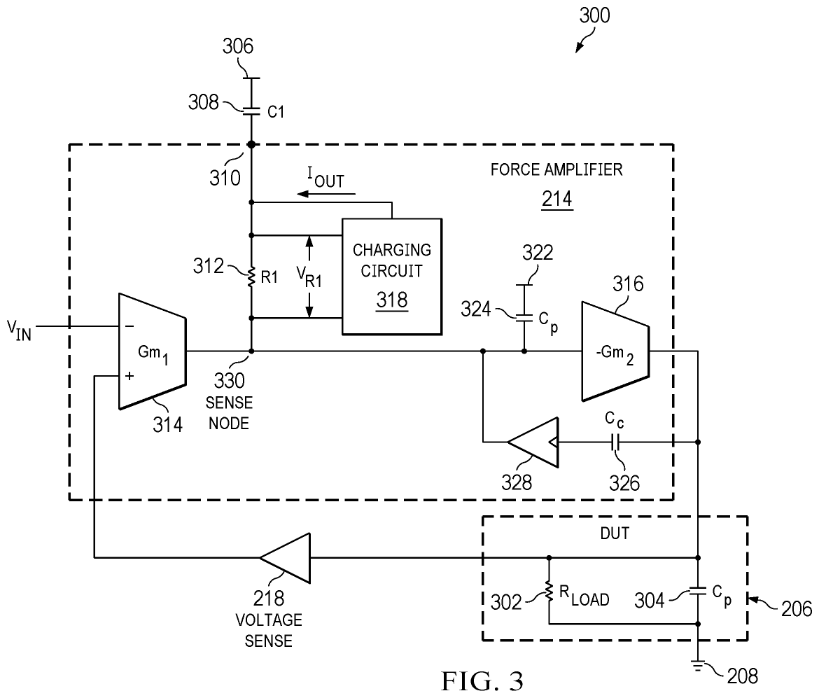

The feedback circuit including the force amp 214 and voltage sense circuit 218 is also referred to as a force voltage feedback loop 300. The force voltage feedback loop 300 is further described with respect to FIG. 3.

FIG. 2B is a functional block diagram of a third example ATE system 241. A functional block including the force DAC 210 and gain circuit 212 includes a first differential amplifier 243, a first resistor 244, a variable resistor 246, a reference ground terminal 248, a first buffer 250, an eighth switch 251, and an offset DAC 252. The force amp 214 includes a clamp DAC hi circuit 254, a clamp DAC lo circuit 256, a current clamp 258, a second differential amplifier 260, a second buffer 262, and a third buffer 264. The current sense circuit 216 includes a third differential amplifier 266, a fourth differential amplifier 268, a fifth differential amplifier 269, a second resistor 270, a third resistor 272, a fourth resistor 274, a fifth resistor 276, and the reference ground terminal 248. The voltage sense circuit 218 includes a sixth differential amplifier 278, a seventh differential amplifier 280, an eighth differential amplifier 282, a sixth resistor 284, a seventh resistor 286, an eighth resistor 287, a ninth resistor 288, and the reference ground terminal 248. The MPVS circuit 220 includes a voltage scaling circuit 289, a measure current/measure voltage (MI/MV) multiplexer 290, a ninth differential amplifier 291, a ninth switch 292, a diagnosis multiplexer 293, and a tenth switch 294.

In the functional block including the force DAC 210 and gain circuit 212, the force DAC 210 receives a first code (code 1). An output of the force DAC 210 is connected to a non-inverting input of the first differential amplifier 243. An input of the offset DAC 252 receives a second code (code 2). An output of the offset DAC 252 is connected to an input of the first buffer 250.

An output of the first buffer 250 is connected to a first terminal of the eighth switch 251. A reference buffer (not shown) is connected to a second terminal of the eighth switch 251. The reference ground terminal 248 is connected to a third terminal of the eighth switch 251. A fourth terminal of the eighth switch 251 is connected to a first terminal of the variable resistor 246. A throw of the eighth switch 251 can couple its fourth terminal to any of its first, second, or third terminals. A second terminal of the variable resistor 246 is connected to a first terminal of the first resistor 244 and to an inverting input of the first differential amplifier 243. An output of the first differential amplifier 243 is connected to a second terminal of the first resistor 244 and to the output of the gain circuit 212.

A non-inverting input of the second differential amplifier 260 is connected to the first input of the force amp 214. An inverting input of the differential amplifier 260 is connected to the second input of the force amp 214. An output of the clamp DAC hi 254 provides a CLDACH signal to a first input of the current clamp 258. An output of the clamp DAC lo 256 provides a CLDACL signal to a second input of the current clamp 258. An output of the current clamp 258 is connected to an input of the second differential amplifier 260. An output of the second differential amplifier 260 is connected to inputs of the second and third buffers 262 and 264. An output of the second buffer 262 is connected to the second output of the force amp 214, and an output of the third buffer 264 is connected to the first output of the force amp 214.

A non-inverting input of the third differential amplifier 266 is connected to a first input of the current sense circuit 216. An inverting input and an output of the third differential amplifier 266 are connected to a first terminal of the second resistor 270. A second terminal of the second resistor 270 is connected to a non-inverting input of the fifth differential amplifier 269 and a first terminal of the third resistor 272. A second terminal of the third resistor 272 is connected to the reference ground terminal 248.

A non-inverting input of the fourth differential amplifier 268 is connected to a second input of the current sense circuit 216. An inverting input and an output of the fourth differential amplifier 268 are connected to a first terminal of the fourth resistor 274. A second terminal of the fourth resistor 274 is connected to an inverting input of the fifth differential amplifier 269 and a first terminal of the fifth resistor 276. A second terminal of the fifth resistor 276 is connected to an output of the fifth differential amplifier 269 and the output of the current sense circuit 216.

A non-inverting input of the sixth differential amplifier 222 is connected to the first input of the voltage sense circuit. An inverting input and an output of the sixth differential amplifier 222 are connected to a first terminal of the sixth resistor 284. A second terminal of the sixth resistor 284 is connected to a non-inverting input of an eighth differential amplifier 282 and a first terminal of a seventh resistor 286. A second terminal of the seventh resistor 286 is connected to the reference ground terminal 248.

A non-inverting input of the seventh differential amplifier 280 is connected to the second input of the voltage sense circuit 218. An inverting input and an output of the seventh differential amplifier 280 are connected to a first terminal of the eighth resistor 287. A second terminal of the eighth resistor 287 is connected to an inverting input of the eighth differential amplifier 282 and to a first terminal of the ninth resistor 288. A second terminal of the ninth resistor 288 is connected to an output of the eighth differential amplifier 282 and the output of the voltage sense circuit 218.

First and second inputs of the voltage scaling circuit 289 are respectively connected to first and second inputs of the MPVS circuit 220. A first input of the MI/MV multiplexer 290 is connected to a first output of the voltage scaling circuit 289 and a first input of the diagnosis multiplexer 293. A second input of the MI/MV multiplexer 290 is connected to a second output of the voltage scaling circuit 289. An output of the diagnosis multiplexer is connected to a first terminal of the ninth switch 292. A second terminal of the ninth switch is connected to a monitor (MON) pin.

An output of the MI/MV multiplexer 290 is connected to a non-inverting input of the ninth differential amplifier 291. An inverting input of the MI/MV multiplexer 291 is connected to a first terminal of the tenth switch 294. A second terminal of the tenth switch 294 is connected to an MVI pin.

The MON pin and the MVI pin are output pins. The MON pin is used for current measurements, and the MVI pin is used for voltage measurements or current measurements depending on which input of the MI/MV multiplexer 290 is selected. The MON and MVI pins enable simultaneous voltage measurement and current measurement. In some examples, current sense circuit 216 and voltage sense circuit 218 output voltages up to 48 volts. These voltages are scaled down by the MPVS circuit 220, for example to five volts or less, and the scaled down voltages are output using the MON pin and/or the MVI pin.

FIG. 3 is a functional block and circuit diagram of the force voltage feedback loop 300 including the force amp 214 and voltage sense circuit 218 of FIG. 2A. The force voltage loop 300 also includes a first voltage source 306 and a first capacitor 308 with capacitance C1 that is connected to force amp 214 (particularly, to the IC including the force amp 214) via a compensation terminal 310. The DUT 206 is shown connected to the force voltage feedback loop 300. The DUT 206 includes a load resistance 302 with resistance R_{LOAD}, and a load capacitance 304 with capacitance C_{LOAD}. In some examples, the first capacitor 308 is a relatively large on-board capacitor that, along with an on-chip first resistor 312 with resistance R1, is used to compensate for the load capacitance 304, such as for a maximum value of the load capacitance 304. Accordingly, in some examples, the first capacitor 308 is fabricated on a same printed circuit board (PCB) as an IC that includes the force amp 214 or the SMU 202.

In the illustrated example, the force amp 214 is a two stage op amp with two transconductance amplifier cells connected in series between the input of the force amp 214 and the first output of the force amp 214. The force amp 214 includes a first transconductance amplifier 314 with transconductance Gm₁, a second transconductance amplifier 316 with transconductance −Gm₂, a charging circuit 318, a second voltage source 322, a parasitic capacitance 324 with capacitance Cₚ, a compensation capacitor 326 with capacitance C_{c}, and a current buffer 328. The negative sign of the second transconductance −Gm₂ is used to indicate that Gm₁ and Gm₂ have opposite signs. The compensation capacitor 326 provides Miller compensation for the force amp 214.

The first transconductance amplifier 314 has an inverting input that receives an input voltage V_{IN} (for example, V_{FORCE}) at a first input of the force amp 214, and a non-inverting input that is connected to an output of the voltage sense circuit 218. An output of the first transconductance amplifier 314 is connected to a second terminal of the first resistor 312, a second input of the charging circuit 318, an output of the current buffer 328, a second terminal of the parasitic capacitance 324, and an input of the second transconductance amplifier 316. Accordingly, the first transconductance amplifier 314 has differential inputs. And in some examples, the second transconductance amplifier 316 has a single ended input, or differential inputs with a second input of the second transconductance amplifier connected to a signal ground.

A first terminal of the first resistor 312 is connected to a first input and an output of the charging circuit 318, and to a second terminal of the first capacitor 308 via the compensation terminal 310. A voltage across the first resistor 312 is V_{R1}. A first terminal of the first capacitor 308 is connected to the first voltage source 306. A sense node 330 is located between the output of the first transconductance amplifier 314, the second node of the first resistor 312, and the input of the second transconductance amplifier 316.

An output of the second transconductance amplifier 316 is connected to a first terminal of the compensation capacitor 326, a first terminal of the load resistance 302, a first terminal of the load capacitance 304, and an input of the voltage sense circuit 218. The output of the second transconductance amplifier 316 provides the second output of the force amp 214. A second terminal of the compensation capacitor 326 is connected to an input of the current buffer 328. The second terminal of the compensation capacitor 326 is connected to the first output of the force amp 214. A second terminal of the load resistance 302 and a second terminal of the load capacitance 304 are connected to ground 208.

The resistance R₁ of the first resistor 312 and the capacitance C₁ of the first capacitor 308 are used to stabilize the force voltage feedback loop 300, particularly in response to load capacitance. Put differently, R₁ and C₁ are used to provide compensation for force amp 214, which is an op amp in negative feedback driving the load DUT 206 that has resistance R_{LOAD} and capacitance C_{LOAD}. In some examples, R₁ and C₁ are chosen to introduce a zero in a transfer function of the force voltage feedback loop 300 at a frequency responsive to a maximum C_{LOAD} that the SMU 202 is designed to support. Accordingly, in some examples, R₁ and C₁ are determined according to Equations 1 and 2, respectively:

$$\\ \begin{matrix}{R}_{1} = \frac{{C}_{c}}{{C}_{p} {Gm}_{1}} & Equation 1\end{matrix}$$

$$\\ \begin{matrix}{C}_{1} = {C}_{LOAD} ( \frac{{Gm}_{1}}{{Gm}_{2}} ) {( \frac{{C}_{p}}{{C}_{c}} )}^{2} & Equation 2\end{matrix}$$

In an example, the bandwidth of the force amplifier 214 is 200 kilohertz, the range of C_{LOAD} is 0 to 10 microfarads (μF), Gm₁ equals 100 microsiemens (μS), Gm₂ equals 20 mS, C_{c} equals 80 pF, R₁ equals 50 kiloohms (kΩ), and C₁ equals 4.7 nF. In this example, the settling time constant R₁ times C₁ equals 235 microseconds (μs). In some examples corresponding to these parameters, and not using a charging circuit 318, where a 30 volt step change is applied to V_{FORCE} and R_{LOAD} equals 300Ω, and where C_{LOAD} is less than 100 nF, settling time is approximately 750 μs (across the range of C_{LOAD}<100 nF). Where C_{LOAD} equals 10 μF, settling time is approximately 2.6 ms. In some examples corresponding to the described parameter values, and using a charging circuit 318, where a 30 volt step change is applied to V_{FORCE} and R_{LOAD} equals 300Ω, and where C_{LOAD} is less than 100 nF, settling time is approximately 120 μs (across the range of C_{LOAD}<100 nF). Where C_{LOAD} equals 10 μF, settling time is approximately 2.1 ms.

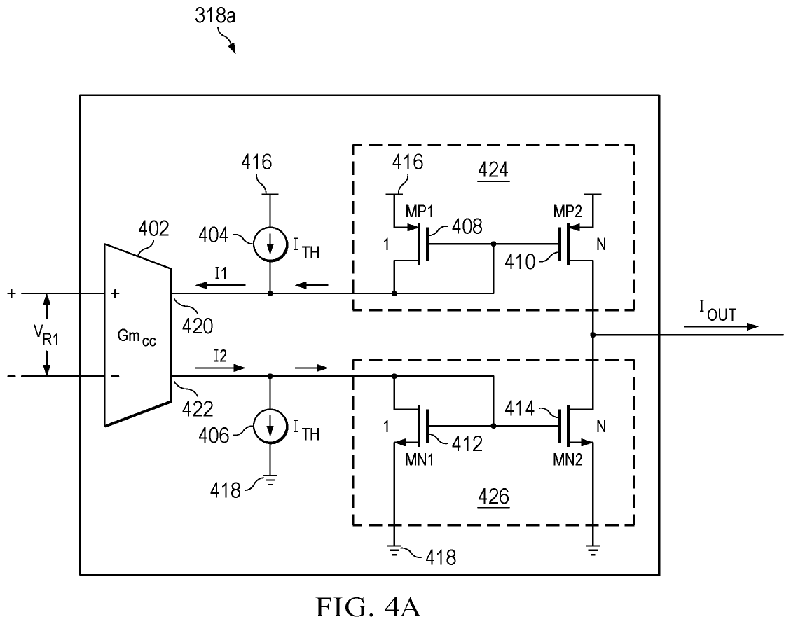

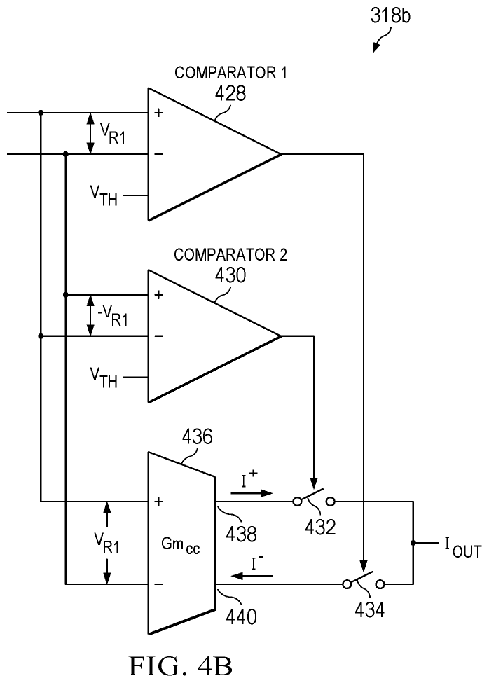

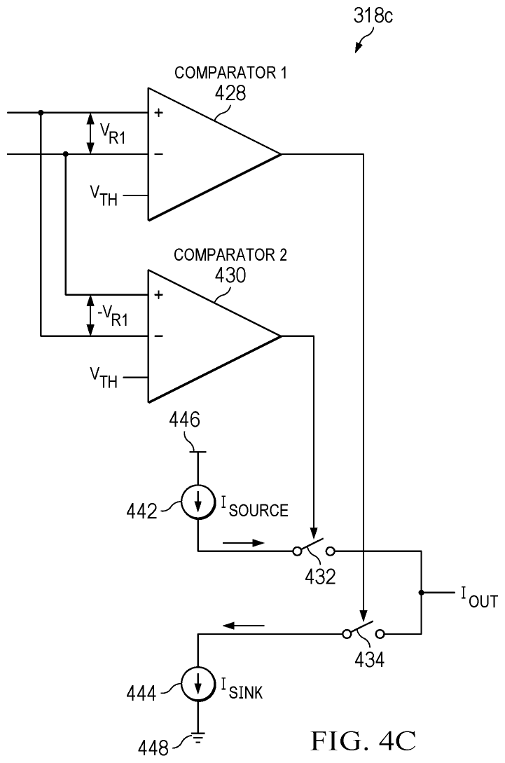

As further described with respect to FIGS. 4A, 4B, and 4C, the charging circuit 318 provides a current (I_{OUT}) responsive to a voltage across the first resistor 312. There is a voltage across the first resistor 312 following a step change in voltage in V_{IN}, until a voltage at the sense node 330 settles. A step change in V_{IN} is responsive to a change in the code input to the SMU 202. In further response, the force DAC 210 induces a change in V_{FORCE}. The voltage at the sense node 330 changes as the first capacitor 308 charges or discharges, depending on whether the step change in V_{IN} is a step change increase or decrease in voltage, respectively. The voltage at the sense node 330 provides an input voltage for the second transconductance amplifier 316. The second transconductance amplifier 316 uses the voltage at the sense node 330 to determine the voltage across the DUT 206.

The voltage source 306 provides a constant voltage. As described, increasing V_{IN} causes the first capacitor 308 to be charged, and decreasing V_{IN} causes the first capacitor 308 to be discharged. The first capacitor 308 discharges if the voltage at the compensation terminal 310 increases, which corresponds to the voltage at the sense node 330 increasing. Accordingly, to discharge the first capacitor 308, a current flows from the sense node 330, through the first resistor 312, into the first capacitor 308. Current through the first resistor 312 into the first capacitor 308 corresponds to negative V_{R1}. The first capacitor 308 charges if the voltage at the compensation terminal 310 decreases, which corresponds to the voltage at the sense node 330 decreasing. Accordingly, a current flows from the first capacitor 308, across the first resistor 312, into the sense node. Current through the first resistor 312 into the sense node 330 corresponds to positive V_{R1}.

In an example, V_{FORCE} is initially V₀, and is then changed to V₁. This is a change in voltage across the DUT 206 of V₁−V₀, so that current drawn by the DUT 206 changes by (V₁−V₀)/R_{LOAD}. The current drawn by the DUT 206 is supplied by the second transconductance amplifier 316. For the current output by the second transconductance amplifier 316 to change by (V₁−V₀)/R_{LOAD}, the input of the second transconductance amplifier 316 changes by −(V₁−V₀)/(R_{LOAD}×Gm₂). Accordingly, the voltage across the first capacitor 308 changes by (V₁−V₀)/(R_{LOAD}×Gm₂).

For V₁−V₀>0 (V_{FORCE} increases), the voltage received by the second transconductance amplifier 316 reduces, so the first capacitor 308 charges. For V₁−V₀<0 (V_{FORCE} decreases), the voltage received by the second transconductance amplifier 316 increases, so the first capacitor 308 discharges.

Current (I_{Gm1}) provided by the first transconductance amplifier 314 is proportional to the voltage difference (VDIFF) between V_{FORCE} and the voltage across the DUT 206. I_{Gm1}=Gm₁×V_{DIFF}. After V_{FORCE} changes, initially, V_{DIFF}=V₁−V₀. V_{DIFF} reduces to zero as the voltage across the DUT 206 settles to equal V_{FORCE}. A maximum value of I_{Gm1} (I_{Gm1_max}) is limited by a current provided by a current source (not shown) used to bias the first transconductance amplifier 314.

Without the charging circuit 318, the rate of charging or discharging of the first capacitor 308 equals I_{Gm1}/C1, and is limited by I_{Gm1} max/C1. With current (I_{OUT}) provided by the charging circuit 318, the rate of charging or discharging of the first capacitor 308 equals (I_{Gm1}+I_{OUT})/C1. Accordingly, a charge or discharge of the first capacitor 308 is increased in proportion to I_{OUT}, and a maximum rate of charge or discharge is increased in proportion to a maximum I_{OUT}.

FIG. 4A is a circuit diagram of a first example 318a of the charging circuit 318 of FIG. 3. MOSFETS are numbered as M[channel type][number], where the number increases for each differing transistor of a same channel type. The charging circuit 318a includes a transconductance amplifier 402 with transconductance Gm_{CC}, a first current source 404 providing a current I_{TH} (a threshold current), a second current source 406 providing the current I_{TH}, a first p-channel MOSFET (MP1) 408, a second p-channel MOSFET (MP2) 410, a first n-channel MOSFET (MN1) 412, a second n-channel MOSFET (MN2) 414, a relatively high voltage reference 416 (for example, a voltage source), and a relatively low voltage reference 418 (for example, a ground).

A non-inverting input of the transconductance amplifier 402 is connected to the first terminal of the first resistor 312 (on the voltage source 306 side of the first resistor 312). An inverting input of the transconductance amplifier 402 is connected to the second terminal of the first resistor 312 (see FIG. 3). The transconductance amplifier 402 includes a current sinking output 420 providing a (negative) current I₁, and a current sourcing output 422 providing a (positive) current I₂.

The current sinking output 420 of the transconductance amplifier 402 is connected to a second terminal of the first current source 404, a drain and a gate of MP1 408, and a gate of MP2 410. A first terminal of the first current source 404, a source of MP1 408, and a source of MP2 410 are connected to the voltage source 416.

The current sourcing output 422 of the transconductance amplifier 402 is connected to a first terminal of the second current source 406, a drain and a gate of MN1 412, and a gate of MN2 414. A second terminal of the second current source 406, a source of MN1 412, and a source of MN2 414 are connected to ground 418. A drain of MP2 410 is connected to a drain of MN2 414 and to the output of the charging circuit 318a, which provides an output current, I_{OUT}.

MP1 408 and MP2 410 are together a first current mirror 424 with a multiplier N, and MN1 412 and MN2 414 are together a second current mirror 426 with the multiplier N. Thus, current responses of MP1 408 and MP2 410 are matched, and current responses of MN1 412 and MN2 414 are matched. Accordingly, a source-drain current through MP2 410 equals N times a source-drain current through MP1 408, and a source-drain current through MN2 414 equals N times a source-drain current through MN1 412.

I₁ equals GM_{CC} times V_{R1}, and I_{TH} equals GM_{CC} times a threshold voltage VTH. Accordingly, I₁ is greater than I_{TH} if V_{R1} is less (more negative) than negative VTH, corresponding to the first capacitor 308 discharging. Thus, I₁ is greater than I_{TH} if both V_{R1} and VTH have negative values, and a magnitude of V_{R1} is greater than a magnitude of V_{TH}. If I₁ is greater than I_{TH}, then MP1 408 and MP2 410 turn on, and there is a source-drain current I₁ minus I_{TH} through MP1 408. The current I₁−I_{TH} is reflected by the first current mirror 424 as a source-drain current N×(I₁−I_{TH}) through MP2 410. This causes a positive (sourcing) current N×(I₁−I_{TH}), flowing from the voltage source 416, to be provided as I_{OUT}. If I₁ is less than I_{TH}, then MP1 408 and MP2 410 turn off (or remain off), and I₁ does not contribute to I_{OUT}.

I₂ also equals GM_{CC} times V_{R1}, with an opposite polarity to I₁. Accordingly, I₂ is greater than I_{TH} if V_{R1} is greater than V_{TH}, corresponding to the first capacitor 308 charging. If I₂ is greater than I_{TH}, then MN1 412 and MN2 414 turn on, and there is a drain-source current I₂ minus I_{TH} through MN1 412. The current I₂−I_{TH} is reflected by the current mirror as a drain-source current N×(I₂−I_{TH}) through MN2 414. This causes a negative (sinking) current −N×(I₁−I_{TH}), flowing to ground 418, to be provided as I_{OUT}. If I₂ is less than I_{TH}, then MN1 412 and MN2 414 turn off (or remain off), and I₂ does not contribute to I_{OUT}.

Note that if V_{R1} is between positive and negative V_{TH}, then I_{OUT} equals zero. Thus, V_{R1} is between positive and negative V_{TH} if I₁ and I₂ are each, respectively, less than I_{TH}. This corresponds to a dead zone of operation of the charging circuit 318a, in which the charging circuit 318 does not provide current (turns off). The dead zone is provided so that the charging circuit 318 does not provide current while the force amp 214 is operating in a steady state, accordingly, after the output of the force amp 214 has settled to the controlled value. This avoids instability in force amp 214 output current potentially caused by ongoing operation of the charging circuit 214.

Equations 3, 4, and 5 give I_{OUT} as a function of Gm_{CC}, V_{R1}, and V_{TH}:

$$\\ \begin{matrix}{V}_{R 1} < - {V}_{TH} = > {I}_{OUT} = N \times ( {I}_{1} - {I}_{TH} ) = N \times {Gm}_{CC} \times ( {V}_{R 1} - {V}_{TH} ) & Equation 3\end{matrix}$$

$$\\ \begin{matrix}{V}_{R 1} > {V}_{TH} = > {I}_{OUT} = - N \times ( {I}_{2} - {I}_{TH} ) = - N \times {Gm}_{CC} \times ( {V}_{R 1} - {V}_{TH} ) & Equation 4\end{matrix}$$

$$\\ \begin{matrix}- {V}_{TH} < {V}_{R 1} < {V}_{TH} = > {I}_{OUT} = 0 & Equation 5\end{matrix}$$

Accordingly, the charging circuit 318a μses a voltage V_{R1} across an on-chip resistor (the first resistor 312) to detect whether the compensation capacitor (the first capacitor 308) is charging or discharging, in response to a threshold voltage ±V_{TH} used to provide hysteresis. If a magnitude (absolute value) of V_{R1} is greater than a magnitude of V_{TH}, then the charging circuit 318a provides a positive or negative current I_{OUT} (depending on a polarity of V_{R1}) proportional to a difference between V_{R1} and V_{TH}. Note that V_{R1} being less than negative V_{TH} is equivalent to negative V_{R1} being greater than (or equal to) V_{TH}. Negative V_{R1} refers to V_{R1} with the same magnitude and an opposite sign.

Given the preceding, the charging or discharging of the first capacitor 308 results in a corresponding and respective negative or positive value of I_{OUT} and an increased charging rate or discharging rate. Specifically, while the first capacitor 308 is charging, a current flows through the first resistor 312 to the sense node 330, so that V_{R1} is positive. In response to a positive V_{R1} greater than a positive V_{TH}, the charging circuit 318a provides a negative I_{OUT} to increase the rate of charging of the first capacitor 308. As described, negative I_{OUT} corresponds to current flowing from the first capacitor 308 into the charging circuit 318a. While the first capacitor 308 is discharging, a current flows through the first resistor 312 to the first capacitor 308, so that V_{R1} is negative. In response to a negative V_{R1} less than a negative V_{TH}, the charging circuit 318a provides a positive I_{OUT} to increase the rate of discharging the first capacitor 308. As described, positive I_{OUT} corresponds to current flowing from the charging circuit 318 into the first capacitor 308.

FIG. 4B is a circuit diagram of an alternative example 318b of the charging circuit 318 of FIG. 3. The charging circuit 318b includes a first comparator (comparator 1) 428, a second comparator (comparator 2) 430, a first switch 432, a second switch 434, and a transconductance amplifier 436 with a transconductance Gm_{CC}.

A non-inverting input of the first comparator 428 is connected to the first terminal of the first resistor 312, and an inverting input of the first comparator 428 is connected to the second terminal of the first resistor 312. Together, the non-inverting and inverting inputs of the first comparator 428 receive the voltage V_{R1}. A third input of the first comparator 428 receives (positive) V_{TH}. If V_{R1} is greater than V_{TH}, corresponding to the first capacitor 308 charging, then the first comparator 428 outputs a signal corresponding to a logical one. Otherwise, the first comparator 428 outputs a signal corresponding to a logical zero.

A non-inverting input of the second comparator 430 is connected to the second terminal of the first resistor 312, and an inverting input of the second comparator 430 is connected to the first terminal of the first resistor 312. Together, the non-inverting and inverting inputs of the second comparator 430 receive the voltage −V_{R1} (negative V_{R1}, i.e., V_{R1} with an opposite polarity). A third input of the second comparator 430 receives (positive) V_{TH}. If −V_{R1} is greater than V_{TH}, corresponding to the first capacitor 308 discharging, then the second comparator 430 outputs a signal corresponding to a logical one. Otherwise, the second comparator 430 outputs a signal corresponding to a logical zero.

A non-inverting input of the transconductance amplifier 436 is connected to the first terminal of the first resistor 312, and an inverting input of the transconductance amplifier 436 is connected to the second terminal of the first resistor 312. A current sourcing output 438 of the transconductance amplifier 436 provides a positive current I⁺, and a current sinking output 440 of the transconductance amplifier 436 provides a negative current I⁻. The current sourcing output 438 is connected to a first terminal of the first switch 432, and the current sinking output 440 is connected to a first terminal of the second switch 434. The second terminals of the first and second switches 432 and 434 are connected to the output of the charging circuit 318b to provide I_{OUT}. An output of the first comparator 428 is connected to a control terminal of the second switch 434, and an output of the second comparator 430 is connected to a control terminal of the first switch 432.

As described above, if the first comparator 428 determines that V_{R1} is greater than V_{TH} (corresponding to the first capacitor 308 discharging), then the first comparator 428 outputs a signal corresponding to a logical one. Responsive to the logical one, the second switch 434 closes, and the charging circuit 318b provides the negative current I⁻ as I_{OUT}. This corresponds to Equation 4. Otherwise, the second switch 434 remains open and I⁻ does not contribute to I_{OUT}.

The second comparator 430 determines whether negative V_{R1} is greater than (or equal to) V_{TH}, corresponding to the first capacitor 308 charging. As described above, this is equivalent to determining whether V_{R1} is less than negative V_{TH}. If the second comparator 430 determines that negative V_{R1} is greater than V_{TH}, then the second comparator 430 outputs a signal corresponding to a logical one. Responsive to the logical one, the first switch 432 closes, and the charging circuit 318b provides the positive current I⁺ as I_{OUT}. This corresponds to Equation 3. Otherwise, the first switch 432 remains open and I⁺ does not contribute to I_{OUT}.

Accordingly, if V_{R1} and negative V_{R1} are both less than V_{TH}, then Jour equals zero. This corresponds to Equation 5.

FIG. 4C is a circuit diagram of another alternative example 318c of the charging circuit 318 of FIG. 3. The charging circuit 318c includes a first current source 442 sourcing a current I_{SOURCE}, a second current source 444 sinking a current I_{SINK}, a relatively high voltage reference (such as a voltage source) 446, and a relatively low voltage reference (such as a ground) 448. A first terminal of the first current source 442 is connected to the voltage source 446, and a second terminal of the first current source 442 is connected to the first terminal of the first switch 432. A first terminal of the second current source 444 is connected to the first terminal of the second switch 434, and a second terminal of the second current source 444 is connected to ground 448.

If the first comparator 428 determines that V_{R1} is greater than V_{TH}, the first comparator 428 outputs a signal corresponding to a logical one. Responsive to the logical one, the second switch 434 closes. Responsive to the second switch 434 closing, I_{OUT} equals I_{SINK}, i.e., a negative output current. If the second comparator 430 determines that negative V_{R1} is greater than V_{TH}, the second comparator 430 outputs a signal corresponding to a logical one. Responsive to the logical one, the first switch 432 closes. Responsive to the first switch 432 closing, I_{OUT} equals I_{SOURCE}, i.e., a positive output current. If V_{R1} and negative V_{R1} are both less than V_{TH}, then Jour equals zero. In some examples, I_{SOURCE} and I_{SINK} are proportional to V_{R1}, or to a current through the first resistor 312.

In some examples, I_{SOURCE} and I_{SINK} have equal magnitudes and opposite polarities. In some examples, I_{SOURCE} and I_{SINK} have different magnitudes and opposite polarities.

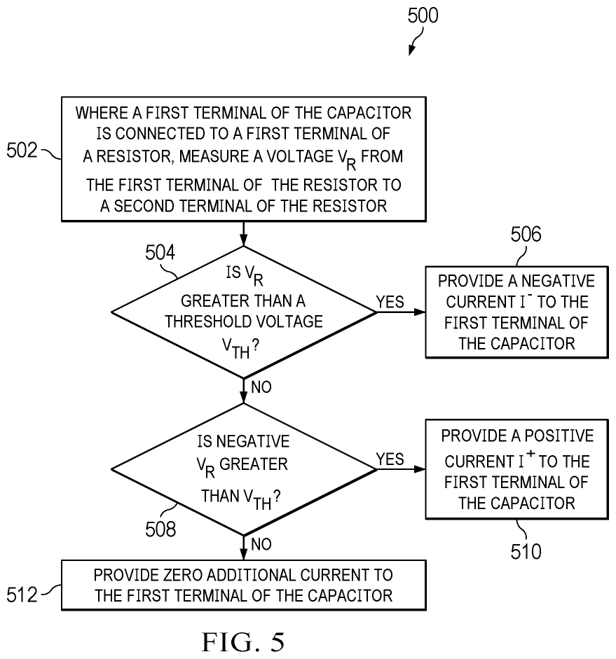

FIG. 5 is an example process 500 for charging and discharging an RC circuit that includes a capacitor and a resistor.

In block 502, where a first terminal of the capacitor is connected to a first terminal of a resistor, measure a voltage VR from the first terminal of the resistor to a second terminal of the resistor. In block 504, compare VR to a threshold voltage V_{TH}. In block 506, if V_{R} is greater than V_{TH}, then provide a negative current I⁻ to the first terminal of the capacitor. The negative current I⁻ is provided by sinking a current of magnitude I⁻ from the first terminal of the capacitor. In block 508, compare negative V_{R} to V_{TH}. In block 510, if negative V_{R} is greater than V_{TH}, then provide a positive current I⁺ to the first terminal of the capacitor. The positive current I⁺ is provided by sourcing a current of magnitude I⁺ to the first terminal of the capacitor. In block 512, if V_{R} is not greater than V_{TH} and negative V_{R} is not greater than V_{TH} (Equation 5), then provide zero additional current to the first terminal of the capacitor.

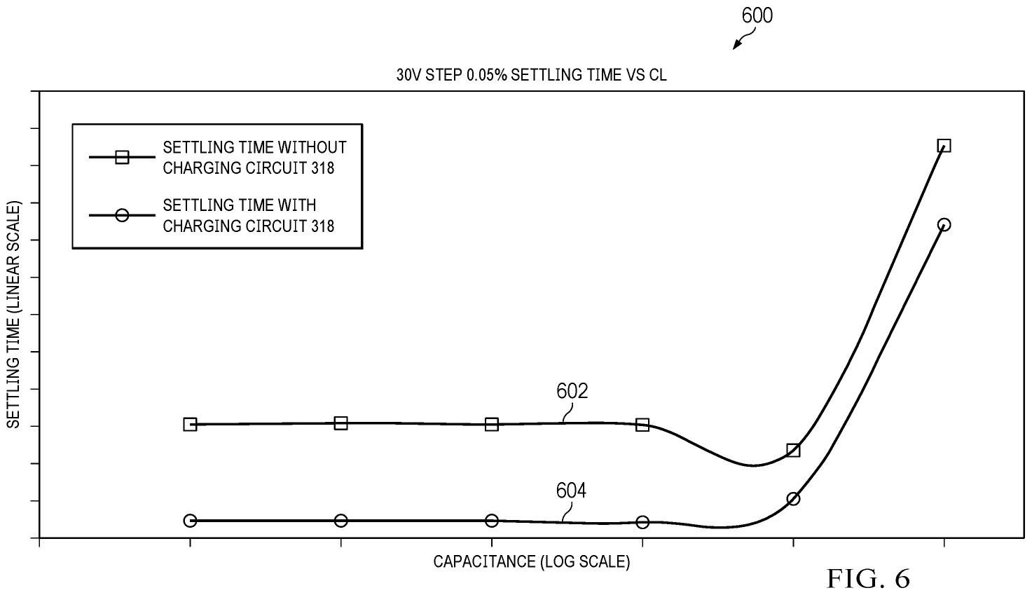

FIG. 6 is an example graph 600 of force voltage settling time against load capacitance for the force voltage feedback loop 300 of FIG. 3, with and without the charging circuit 318 of FIG. 3. The horizontal axis corresponds to load capacitance represented using a log scale. The vertical axis corresponds to settling time represented using a linear scale. The graph 600 includes a first curve 602 showing settling time for the force voltage feedback loop 300 (or the voltage across the DUT 206) without the charging circuit 318. The graph 600 also includes a second curve 604 showing settling time for the force voltage feedback loop 300 with the charging circuit 318. At relatively low and middling load capacitances, a reduction in settling time predominates over a slew time substantially unaffected by the charging circuit 318, resulting in a relatively large proportional decrease in total settling time shown in the second curve 604. At relatively high capacitances, the slew time, which is substantially unaffected by the charging circuit 318, predominates over the reduction in settling time. Accordingly, there is a relatively smaller proportional decrease in total settling time shown in the second curve 604.

Modifications are possible in the described examples, and other examples are possible within the scope of the claims.

In some examples, a charging circuit as described herein is used to charge an RC circuit in an op amp in a PMU, SMU, DPS, or other DUT (or other) test control circuit or other signal control circuit. In some examples, a charging circuit as described herein is used to charge an RC circuit in a context other than an operation amplifier, such as a force amplifier, in a PMU, SMU, DPS, or other DUT test control circuit. In some examples, a charging circuit as described herein is used to charge an RC circuit in an op amp. In some examples, a charging circuit as described herein is used to charge an RC circuit used to compensate for a variable load capacitance.

In some examples, methods and systems described herein enable accelerated voltage settling time of an RC compensation circuit for an op amp across a wide range of load capacitances without using multiple different on-board (or on-chip) compensation capacitors to address different portions of the load capacitance range.

In some examples, the charging circuit 318 provides a first current if V_{R1} exceeds a first threshold, and provides a second current if −V_{R1} exceeds a second threshold. In some examples, the first threshold and the second threshold are different.

In some examples, the charging circuit 318 provides a first current if I₁ exceeds a first threshold, and provides a second current if I₂ exceeds a second threshold, where I₁ and I₂ are outputs of the transconductance amplifier 402. In some examples, the first threshold and the second threshold are different.

In some examples, the first current and the second current have equal magnitudes and opposite polarities. In some examples, the first current and the second current have different magnitudes and opposite polarities.

In some examples, the ATE system 100 of FIG. 1 is implemented using analog or digital circuits, or a combination thereof. In some examples, the ATE system 100 is implemented using a processor such as a DSP and/or a microprocessor.

In some examples, the ATE system 200 of FIG. 2A is implemented using analog or digital circuits, or a combination thereof. In some examples, the ATE system 200 is implemented using a processor such as a DSP and/or a microprocessor.

In some examples, the ATE system 241 of FIG. 1 is implemented using analog or digital circuits, or a combination thereof. In some examples, the ATE system 241 is implemented using a processor such as a DSP and/or a microprocessor.

In some examples, the process 500 of FIG. 5 is implemented using programmable circuits executing software or firmware.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, “ball” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples may be included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

What is claimed is:

1. An integrated circuit (IC) comprising:
a resistor including a first terminal and a second terminal; and
a charging circuit including:
a transconductance amplifier including a first input, a second input, a first output, and a second output, the first input of the transconductance amplifier coupled to the first terminal of the resistor, and the second input of the transconductance amplifier coupled to the second terminal of the resistor;
a first current source including a first terminal and a second terminal;
a first transistor including a first terminal, a second terminal, and a gate;
a second transistor including a first terminal, a second terminal, and a gate, the first output of the transconductance amplifier coupled to the first terminal of the first current source, the first terminal and gate of the first transistor, and the gate of the second transistor;
a second current source including a first terminal and a second terminal;
a third transistor including a first terminal, a second terminal, and a gate; and
a fourth transistor including a first terminal, a second terminal, and a gate, the second output of the transconductance amplifier coupled to the first terminal of the second current source, the first terminal and gate of the third transistor, and the gate of the fourth transistor, and the second terminal of the fourth transistor coupled to the second terminal of the second transistor and the first terminal of the resistor.

2. The IC of claim 1,
wherein the first and second transistors are p-channel metal-oxide-semiconductor field effect transistors (MOSFETs); and
wherein the third and fourth transistors are n-channel MOSFETS.

3. The IC of claim 1,
wherein the first output of the transconductance amplifier is configured to sink a current in response to a positive voltage, that exceeds a first threshold, from the first terminal of the resistor to the second terminal of the resistor; and
wherein the second output of the transconductance amplifier is configured to source a current in response to a positive voltage, that exceeds a second threshold, from the first terminal of the resistor to the second terminal of the resistor.

4. The IC of claim 1,
wherein the first current source is configured to source a current from its first terminal; and
wherein the second current source is configured to sink a current to its first terminal.

5. The IC of claim 1,
wherein the first transistor and the second transistor form a first current mirror, so that a current from the first terminal to the second terminal of the second transistor is a multiple greater than one of a current from the second terminal to the first terminal of the first transistor; and
wherein the third transistor and the fourth transistor form a second current mirror, so that a current from the first terminal to the second terminal of the fourth transistor is a multiple greater than one of a current from the second terminal to the first terminal of the third transistor.

6. The IC of claim 1, further comprising:
a capacitor; and
a printed circuit board (PCB);
wherein the capacitor and the IC are coupled to the PCB, and the capacitor is coupled to the resistor.

7. The IC of claim 1, wherein the charging circuit is configured to not provide current to the first terminal of the resistor during a steady state operation of the IC.

8. An integrated circuit (IC) comprising:
a resistor including a first terminal and a second terminal; and
a charging circuit including:
a first comparator including a first input, a second input, and a third input, the first input of the first comparator coupled to the first terminal of the resistor, the second input of the first comparator coupled to the second terminal of the resistor, and the third input of the first comparator configured to receive a threshold voltage;
a second comparator including a first input, a second input, and a third input, the first input of the second comparator coupled to the second terminal of the resistor, the second input of the second comparator coupled to the first terminal of the resistor, and the third input of the second comparator configured to receive the threshold voltage;
a first current source including a first terminal and a second terminal;
a second current source including a first terminal and a second terminal;
a first switch including a first terminal, a second terminal, and a control terminal, the first terminal of the first switch coupled to the first terminal of the first current source, and the control terminal of the first switch coupled to the output of the second comparator; and
a second switch including a first terminal, a second terminal, and a control terminal, the first terminal of the second switch coupled to the first terminal of the second current source, the control terminal of the second switch coupled to the output of the first comparator; and the second terminals of the first and second switches coupled to the first terminal of the resistor.

9. The IC of claim 8,
wherein the first current source is configured to source a current from its first terminal; and
wherein the second current source is configured to sink a current to its first terminal.

10. The IC of claim 9, further comprising a transconductance amplifier including a first input, a second input, a first output, and a second output, the first input of the transconductance amplifier coupled to the first terminal of the resistor, and the second input of the transconductance amplifier coupled to the second terminal of the resistor;
wherein the first terminal of the first current source and the first terminal of the second current source respectively correspond to the first and second outputs of the transconductance amplifier.

11. The IC of claim 8, further comprising a printed circuit board (PCB), the capacitor and the IC coupled to the PCB, and the capacitor coupled to the resistor.

12. A method of operating an RC circuit, comprising:
measuring a measured voltage from a first terminal of the resistor to a second terminal of the resistor, where a first terminal of a capacitor is connected to the first terminal of the resistor;
comparing the measured voltage to a threshold voltage;
providing a negative current I⁻ to the first terminal of the capacitor in response to the measured voltage being greater than the threshold voltage;
comparing negative one multiplied by the measured voltage to the threshold voltage; and
providing a positive current I⁺ to the first terminal of the capacitor in response to negative one multiplied by the measured voltage being greater than the threshold voltage.

13. The method of claim 11, further comprising providing zero additional current to the first terminal of the capacitor in response to neither the measured voltage nor negative one multiplied by the measured voltage being greater than the threshold voltage.

14. The method of claim 11, wherein at least a portion of the RC circuit is portion of an automatic test equipment (ATE) that is a parametric measurement unit, a supply measurement unit, or a device power supply;
further comprising, prior to the measuring, operating the portion of the ATE in a force voltage mode.

15. A system comprising:
an RC circuit including a resistor coupled to a capacitor; and
a charging circuit coupled to the resistor and to the capacitor, the charging circuit configured to determine a voltage across the resistor, and to provide a current to the capacitor to increase a rate of charging or discharging of the capacitor, so that a magnitude and a polarity of the current are responsive to the voltage across the resistor.

16. The system of claim 15, further including an operational amplifier;
wherein the RC circuit is a compensation circuit of the operational amplifier;
wherein a size of the capacitor is responsive to a maximum capacitance of a load; and
wherein the operational amplifier is adapted to be coupled to the load.

17. The system of claim 16, wherein the operational amplifier is configured to regulate a voltage across the load.

18. The system of claim 16, wherein the operational amplifier is part of a test circuit configured to provide a signal to the load and to measure response signals of the load, and wherein the load is a design under test.

19. The system of claim 15, further comprising:
a printed circuit board (PCB); and
an integrated circuit (IC) on which the resistor is fabricated, the IC and the capacitor coupled to the PCB.

20. The system of claim 19,
wherein the IC includes a parametric measurement unit, a supply measurement unit, or a device power supply; and
wherein the resistor is included in a force amplifier.
